(19) United States
(12) Patent Application Publication
(10) Pub. No.: US 2017/0082664 A1
(43) Pub. Date: Mar. 23, 2017

(54) DC VOLTAGE DETECTOR

(71) Applicant: HASEGAWA ELECTRIC CO., LTD., Hyogo (JP)

(72) Inventor: Hiroshi YAMADA, Hyogo (JP)

(73) Assignee: HASEGAWA ELECTRIC CO., LTD., Hyogo (JP)

(21) Appl. No.: 15/310,922

(22) PCT Filed: May 14, 2015
(86) PCT No.: PCT/JP2015/063903

§ 371 Date: Nov. 14, 2016

(30) Foreign Application Priority Data
Jun. 4, 2014 (JP) 2014-115842

(51) Int. Cl. G01R 19/155; G01R 15/16

(52) U.S. Cl. CPC G01R 19/155; G01R 15/16

(57) ABSTRACT

A DC voltage detector, which is configured to detect the presence or absence of a DC voltage in a detection target (21) through bringing a detection electrode (11) provided inside a housing (23) to a vicinity of the detection target (21), includes an AC generation unit (12) configured to generate an AC current corresponding to the DC voltage through changing a capacitance, the AC generation unit (12) being arranged between an inter-electrode stray capacitance (C₁) formed between the detection target (21) and the detection electrode (11) and a ground stray capacitance (C₂) formed between an internal shield (30) of the housing (23) and a ground.

### TECHNICAL FIELD

The present invention relates to a DC voltage detector configured to detect the presence or absence of a DC voltage in a charging unit of an electric power system installed along a railroad line, in an ordinary house, in a factory, or the like.

### BACKGROUND ART

An electric power system installed along a railroad line, in an ordinary house, in a factory, or the like includes an overhead line or a power line as a charging unit to which a DC voltage is applied. In such an electric power system, there is a case in which electrical work such as maintenance or replacement work is conducted while power is shut down. In this case, through conducting the electrical work after determining the presence or absence of a DC voltage in the charging unit of the electric power system, an electric shock to a worker due to contact with electricity is prevented from occurring.

A DC voltage detector described in Patent Literature 1 is an example of such a DC voltage detector configured to determine the presence or absence of a DC voltage in the charging unit of the electric power system. The DC voltage detector described in Patent Literature 1 is a DC electroscope configured to detect the presence or absence of a DC voltage in an overhead line as a charging unit of an electric power system installed along a railroad line.

The DC electroscope includes a hook-shaped electroscope metal fitting at a tip of an insulating cylinder, a grounding line routed from a rear endportion of the insulating cylinder and connected to the electroscope metal fitting described above via a detection resistor, and a detection unit configured to detect the presence or absence of a DC voltage in the overhead line through measuring a terminal voltage of the detection resistor.

When the DC electroscope is used, a worker ground connects the grounding line routed from the rear end portion of the insulating cylinder to a rail or the like, and then hooks the electroscope metal fitting at the tip of the insulating cylinder on the overhead line and engages the electroscope metal fitting therewith. In this way, through grounding the electroscope metal fitting hooked on the overhead line using the grounding line via the detection resistor and measuring the terminal voltage of the detection resistor using the detection unit, the presence or absence of a DC voltage in the overhead line can be detected. When the overhead line is in a charged state, a worker is informed of the state with a light, a beeper, or the like annexed to the detection unit.

### CITATION LIST

Patent Literature 1: JP 2002-372553 A

### SUMMARY OF INVENTION

### Technical Problem

Incidentally, in relation to a related-art DC voltage detector used as a DC electroscope, an overhead line as a detection target is a bare wire, and the electroscope metal fitting at the tip of the insulating cylinder is brought into contact with the overhead line as a bare wire. In this way, a detection target of the DC voltage detector is required to be a bare wire, and thus, it is difficult for an insulated and coated wire such as a power line to be a detection target. Specifically, when the presence or absence of a DC voltage in an insulated and coated wire such as a power line is attempted to be detected, it is required to remove an insulated and coated portion of the insulated and coated wire and to bring the electroscope metal fitting into contact with a core of the wire. Under present circumstances, an insulated and coated wire cannot be a detection target without removing the insulated and coated portion thereof.

Further, in relation to a DC voltage detector used for a detection target including a grounding circuit, when an overhead line is in a charged state and a DC current from the overhead line to the ground is detected via a detection unit, it is required to ground connect the grounding line. In other words, when the DC voltage detector is used, it is required of a worker to ground connect the grounding line routed from a rear end portion of an insulating cylinder to a rail or the like. This work of ground connecting the grounding line is complicated, which makes it difficult to improve workability.

Accordingly, the present invention has been proposed in view of the problems described above, and an object of the present invention is to provide a DC voltage detector which enables an insulated and coated wire such as a power line to be a detection target and which can detect the presence or absence of a DC voltage even when there is no grounding line.

### Solution to Problem

As technical means to achieve the above-mentioned object, according to one embodiment of the present invention, there is provided a DC voltage detector configured to detect the presence or absence of a DC voltage in a detection target through bringing a detection electrode provided inside a housing to a vicinity of the detection target, the DC voltage detector comprising an AC generation unit configured to generate an AC current corresponding to the DC voltage through changing a capacitance, the AC generation unit being arranged between an inter-electrode stray capacitance formed between the detection target and the detection electrode and a ground stray capacitance formed between an internal shield of the housing and a ground.

According to the one embodiment of the present invention, through changing the capacitance in the AC generation unit, the AC current corresponding to the DC voltage in the detection target is generated. The AC current generated in the AC generation unit flows through a closed loop circuit of the AC generation unit—the ground stray capacitance—the detection target—the inter-electrode stray capacitance—the AC generation unit. This enables detection of the presence or absence of a DC voltage in the detection target based on the AC current that is output from the AC generation unit. In this way, the AC current flows through the inter-electrode stray capacitance and the ground stray capacitance, and thus, an insulated and coated wire such as a power line can be a detection target, and the necessity of a grounding line of the DC voltage detector is eliminated.

It is desired that the AC generation unit according to the one embodiment of the present invention comprise: a variable capacitor connected to an output side of the detection electrode; and a piezoelectric element configured to change a capacitance of the variable capacitor. When the AC generation unit comprises the variable capacitor and the piezoelectric element in this way, a capacitance of the variable capacitor can be changed through giving oscillations to the variable capacitor at an oscillation frequency of the piezoelectric element, and the AC current can be generated with ease through changing the capacitance of the variable capacitor.

It is desired that the internal shield according to the one embodiment of the present invention be formed on a portion inside the housing excluding the detection electrode. This configuration enables enlargement of the ground stray capacitance formed between the internal shield and the ground to the maximum of a capacity of the housing, and thus, the AC current can be generated with further ease.

The DC voltage detector according to the one embodiment of the present invention can be applied to a detection target comprising a grounding circuit. In this case, while a detection target hitherto requires a grounding line of a DC voltage detector, necessity of such a grounding line of the DC voltage detector can be eliminated. Further, the DC voltage detector according to the one embodiment of the present invention can also be applied to a detection target comprising a non-grounding circuit. In this case, the presence or absence of a DC voltage in a detection target which cannot be hitherto detected can be detected.

### Advantageous Effects of Invention

According to the present invention, through including the AC generation unit configured to generate an AC current corresponding to the DC voltage through changing the capacitance between the inter-electrode stray capacitance formed between the detection target and the detection electrode and the ground stray capacitance formed between the internal shield of the housing and the ground, the presence or absence of the DC voltage in the detection target can be detected based on the AC current that is output from the AC generation unit. Thus, an insulated and coated wire such as a power line can be the detection target and versatility of the DC voltage detector is increased. Further, the necessity of the grounding line of the DC voltage detector is eliminated, and thus, workability in electrical work using the DC voltage detector can be improved.

### BRIEF DESCRIPTION OF DRAWINGS

FIG. 1 is a circuit configuration block diagram for illustrating a DC voltage detector according to an embodiment of the present invention.

FIG. 2 is an exploded perspective view for illustrating an internal structure of a housing of the DC voltage detector.

FIG. 3 is a sectional view for illustrating the internal structure of the housing of the DC voltage detector.

FIG. 4 is an exploded perspective view for illustrating an exemplary integral structure of a variable capacitor and a piezoelectric element.

FIG. 5 is a sectional view for illustrating the exemplary integral structure of the variable capacitor and the piezoelectric element.

FIG. 6A is a waveform diagram for showing voltage that is input to a synchronous detection circuit in FIG. 1 when a DC voltage is +400 V.

FIG. 6B is a waveform diagram for showing voltage that is output from the synchronous detection circuit in FIG. 1 when the DC voltage is +400 V.

FIG. 7A is a waveform diagram for showing voltage that is input to the synchronous detection circuit in FIG. 1 when the DC voltage is −400 V.

FIG. 7B is a waveform diagram for showing voltage that is output from the synchronous detection circuit in FIG. 1 when the DC voltage is −400 V.

FIG. 8A is a waveform diagram for showing voltage that is input to the synchronous detection circuit in FIG. 1 when the DC voltage is 0 V.

FIG. 8B is a waveform diagram for showing voltage that is output from the synchronous detection circuit in FIG. 1 when the DC voltage is 0 V.

FIG. 9 is a circuit configuration block diagram for illustrating a DC voltage detector according to another embodiment of the present invention.

### DESCRIPTION OF EMBODIMENTS

An embodiment of a DC voltage detector according to the present invention is described in detail below with reference to the drawings.

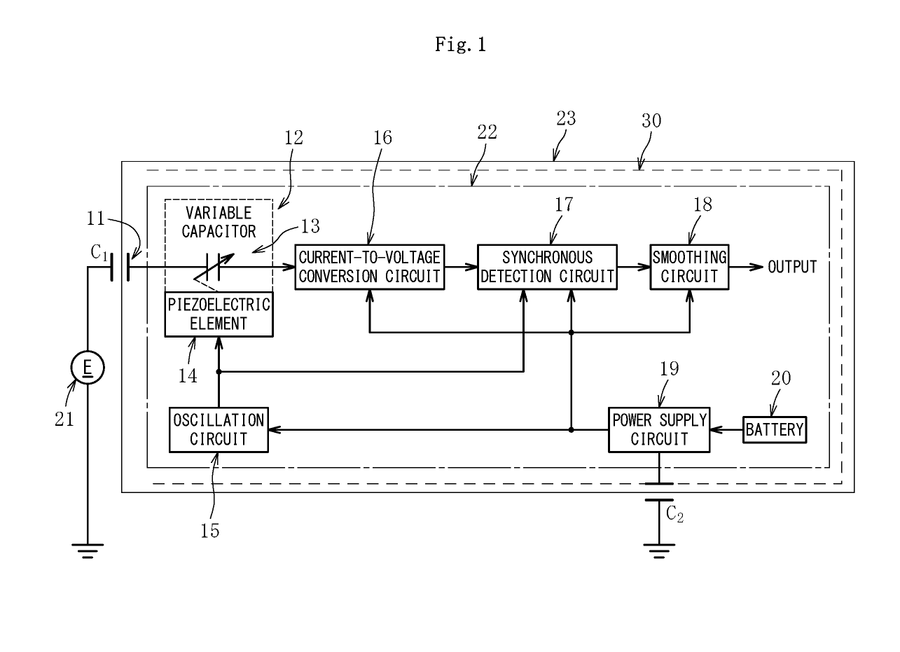

FIG. 1 is an illustration of a schematic circuit configuration of the DC voltage detector according to this embodiment. The DC voltage detector illustrated in FIG. 1 comprises, as a principal part thereof, a detection electrode 11 formed of a conductive member such as a copper plate, a variable capacitor 13 as an AC generation unit 12 connected to the detection electrode 11 and a piezoelectric element 14 annexed to the variable capacitor 13, an oscillation circuit 15 connected to the piezoelectric element 14 forming the AC generation unit 12, a current-to-voltage conversion circuit 16 connected to the variable capacitor 13 forming the AC generation unit 12, a synchronous detection circuit 17 connected to the current-to-voltage conversion circuit 16 and to the oscillation circuit 15, a smoothing circuit 18 connected to the synchronous detection circuit 17, a power supply circuit 19 connected to the oscillation circuit 15, to the current-to-voltage conversion circuit 16, to the synchronous detection circuit 17, and to the smoothing circuit 18, and a power supply 20 such as a battery. The embodiment illustrated in FIG. 1 is an exemplary application of the DC voltage detector when a detection target 21 comprises a grounding circuit.

The detection electrode 11 forms a stray capacitance C₁ with the detection target 21 such as a power line or an overhead line (hereinafter referred to as inter-electrode stray capacitance). The AC generation unit 12 is configured to drive the piezoelectric element 14 with the oscillation circuit 15 and to change a capacitance of the variable capacitor 13 with oscillations generated at a resonance frequency of the piezoelectric element 14. The current-to-voltage conversion circuit 16 is configured to convert an AC current that is output from the variable capacitor 13 to an AC voltage. The synchronous detection circuit 17 is configured to synchronize output from the current-to-voltage conversion circuit 16 and output from the oscillation circuit 15 and to perform detection. The smoothing circuit 18 is configured to smooth output from the synchronous detection circuit 17. The power supply circuit 19 is configured to supply a power supply voltage based on the battery to the oscillation circuit 15, the current-to-voltage conversion circuit 16, the synchronous detection circuit 17, and the smoothing circuit 18.

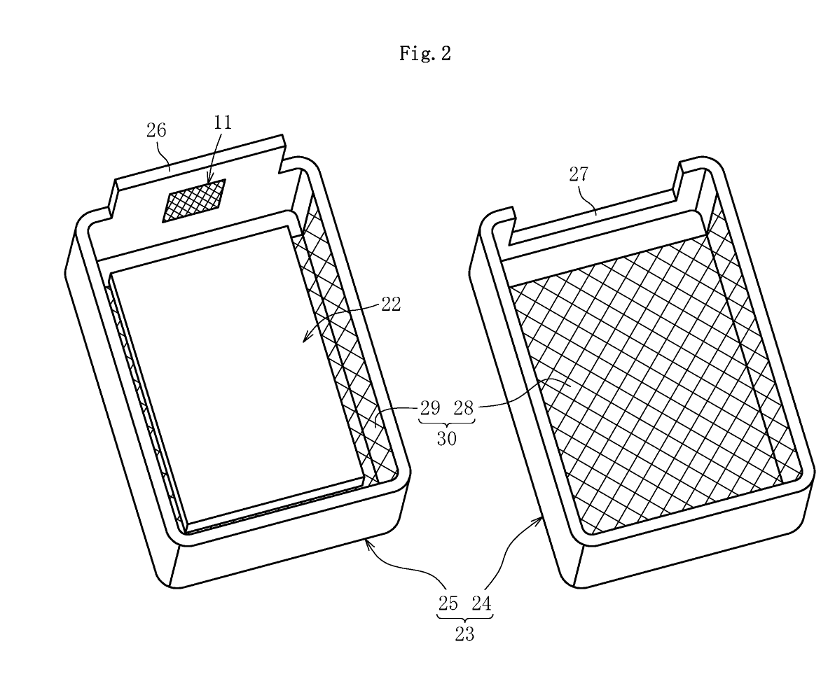

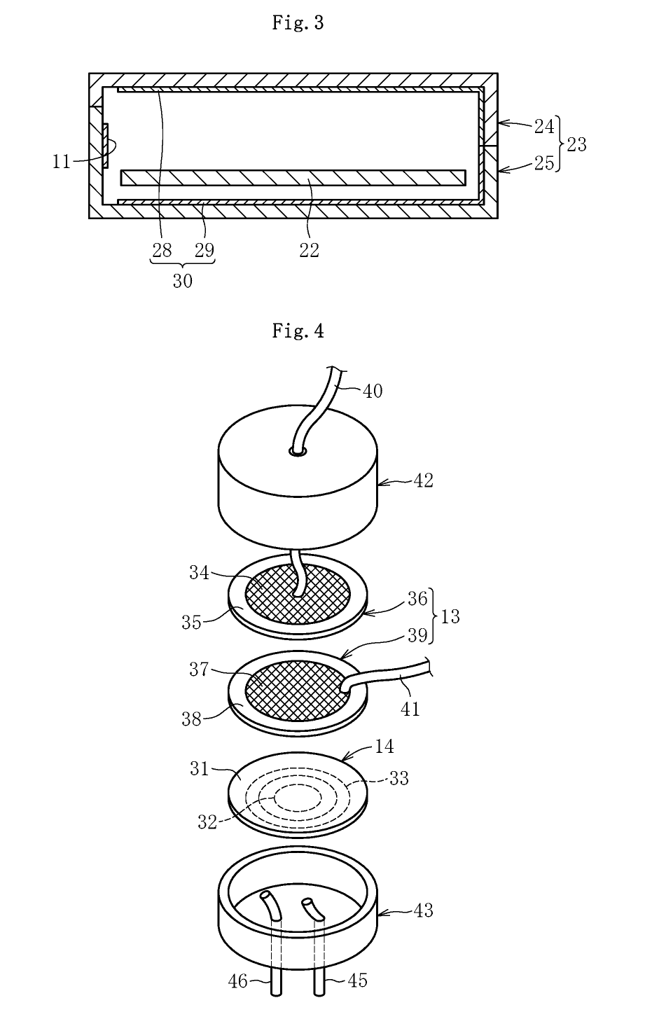

The variable capacitor 13 and the piezoelectric element 14 of the AC generation unit 12, the oscillation circuit 15, the current-to-voltage conversion circuit 16, the synchronous detection circuit 17, the smoothing circuit 18, and the power supply circuit 19 described above are mounted on a wiring board 22. As illustrated in FIG. 2 and FIG. 3, the wiring board 22 is housed in a housing 23 formed of an insulating material such as a resin. The housing 23 has a two-segment structure including an upper housing 24 and a lower housing 25. The upper housing 24 and the lower housing 25 are joined to be integral so that a convex wall portion 26 fits into a concave wall portion 27 using an adhesive. The two-segment structure of the housing 23 illustrated in FIG. 2 and FIG. 3 is only an exemplary structure, and other structures may also be adopted.

In the housing 23, a strip-like detection electrode 11 is adhered and fixed, using an adhesive or the like, to an inner surface of the convex wall portion 26 of the housing 23 so as to be, when the DC voltage detector is used, arranged opposed to the detection target 21, and is electrically connected to the variable capacitor 13 mounted on the wiring board 22. Sheet-like or plate-like shield members 28 and 29 formed of a conductive member such as copper are adhered and fixed, using an adhesive or the like, to inner surfaces of the upper housing 24 and the lower housing 25, respectively, of the housing 23. Through joining the upper housing 24 and the lower housing 25 to be integral, the shield member 28 on the upper housing 24 and the shield member 29 on the lower housing 25 form an internal shield 30 arranged inside the housing 23 and surrounding the wiring board 22.

The internal shield 30 is formed on portions excluding the detection electrode 11, that is, excluding the convex wall portion 26 of the lower housing 25 to which the detection electrode 11 is adhered and the concave wall portion 27 of the upper housing 24. The internal shield 30 is electrically connected to the power supply circuit 19 mounted on the wiring board 22, and forms a stray capacitance C₂ with the ground (hereinafter referred to as ground stray capacitance) (see FIG. 1).

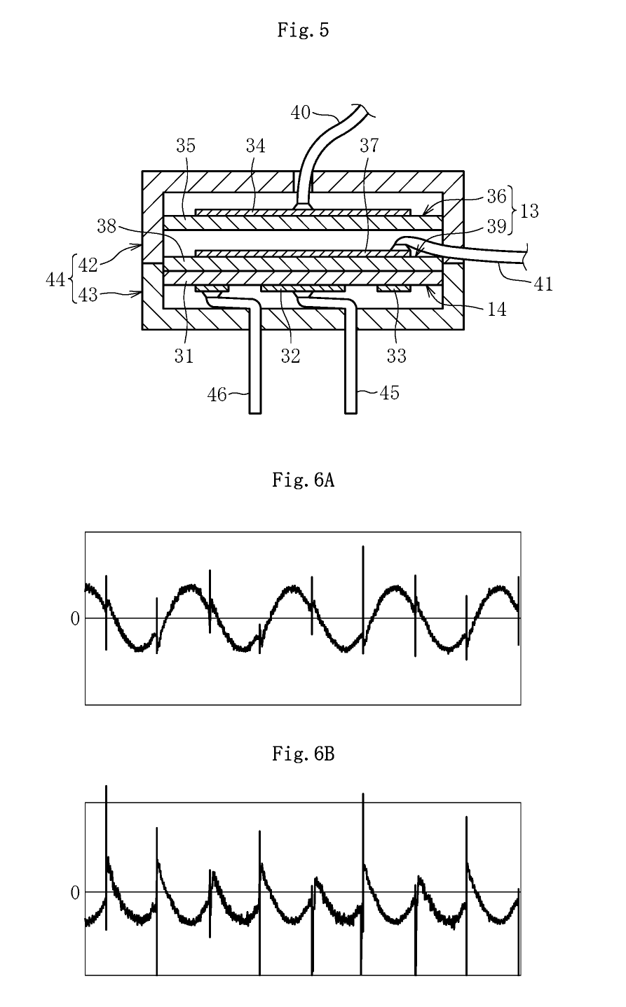

Further, as illustrated in FIG. 4 and FIG. 5, the variable capacitor 13 and the piezoelectric element 14 forming the AC generation unit 12 have an integrated structure housed inside a case 44 formed of an insulating material such as a resin. The case 44 has a two-segment structure including a lid-like upper case 42 and a base-like lower case 43. The upper case 42 and the lower case 43 are joined to be integral using an adhesive or the like. The two-segment structure of the case 44 illustrated in FIG. 4 and FIG. 5 is only an exemplary structure, and other structures may also be adopted.

The piezoelectric element 14 is formed through forming one circular electrode 32 in a center portion on a rear surface (lower surface in FIG. 4 and FIG. 5) of an insulating film 31 and forming an annular electrode 33 around the circular electrode 32. On the other hand, the variable capacitor 13 comprises a fixed electrode portion 36 in which one electrode 34 is formed on a front surface (upper surface in FIG. 4 and FIG. 5) of an insulating film 35 and a movable electrode portion 39 arranged opposed to the fixed electrode portion 36 with a gap therebetween in which another electrode 37 is formed on a front surface (upper surface in FIG. 4 and FIG. 5) of an insulating film 38.

The one electrode 34 of the fixed electrode portion 36 and the another electrode 37 of the movable electrode portion 39 can be realized through evaporating a conductive member onto the insulating films 35 and 38 or adhering a plate-like conductive member to the insulating films 35 and 38, respectively. A lead wire 40 is routed from a center portion of the one electrode 34 of the fixed electrode portion 36, and a lead wire 41 is routed from an end portion of the another electrode 37 of the movable electrode portion 39. In the illustrated example, the variable capacitor 13 and the piezoelectric element 14 are circular, but the two maybe rectangular.

The one fixed electrode portion 36 forming the variable capacitor 13 is housed in and fixed to the upper case 42 with the surface thereof having the one electrode 34 formed thereon facing upward. The lead wire 40 extending from the fixed electrode portion 36 is routed from an upper surface of the upper case 42 to be connected to the detection electrode 11. Further, the another movable electrode portion 39 forming the variable capacitor 13 is adhered and fixed to a surface having no electrode formed thereon of the piezoelectric element 14 with the surface thereof having the another electrode 37 formed thereon facing upward. The leadwire 41 extending from the movable electrode portion 39 is routed sideways from a portion at which the upper case 42 and the lower case 43 are joined to be connected to the current-to-voltage conversion circuit 16 on the wiring board 22.

The piezoelectric element 14 to which the movable electrode portion 39 of the variable capacitor 13 is fixed is housed in and fixed to the lower case 43 with the surface thereof having the electrodes formed thereon facing downward. One lead terminal 45 of two lead terminals 45 and 46 provided in the lower case 43 is connected to the circular electrode 32 of the piezoelectric element 14 and another lead terminal 46 is connected to the annular electrode 33 of the piezoelectric element 14. Through soldering the two lead terminals 45 and 46 routed from the lower case 43 to the wiring board 22, the variable capacitor 13 and the piezoelectric element 14 are mounted on the wiring board 22.

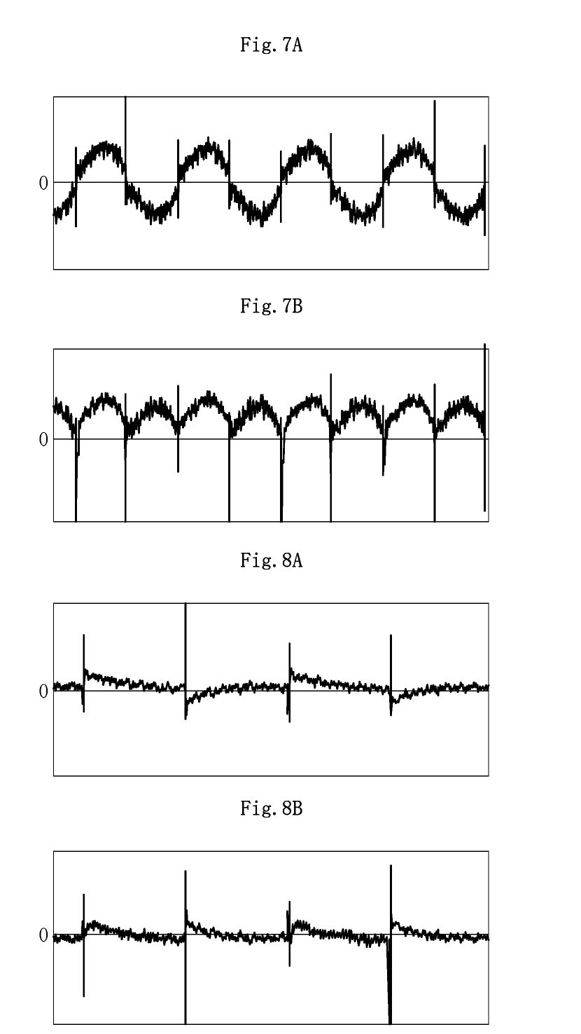

Operation of the DC voltage detector having the circuit configuration as illustrated in FIG. 1 to FIG. 5 and the structures of the housing 23 and the AC generation unit 12 is described in detail below with reference to the waveform diagrams of FIG. 6A, FIG. 6B, FIG. 7A, FIG. 7B, FIG. 8A, and FIG. 8B. FIG. 6A and FIG. 6B are waveform diagrams for showing a case in which the detection target 21 is in a charged state at a DC voltage of +400 V, and FIG. 7A and FIG. 7B show a case in which the detection target 21 is in a charged state at a DC voltage of −400 V. In this way, there are cases where a side of the detection target 21 on which the inter-electrode stray capacitance C₁ is formed is a positive electrode (see FIG. 6A and FIG. 6B) and a side on which the inter-electrode stray capacitance C₁ is formed is a negative electrode (see FIG. 7A and FIG. 7B). FIG. 8A and FIG. 8B are waveform diagrams for showing a case in which the detection target 21 is in a power shut down state at a DC voltage of 0 V.

When the DC voltage detector is used, an outer side surface of the convex wall portion 26 of the housing 23 is brought to the vicinity of the detection target 21. At this time, the detection target 2l maybe contacted or non-contacted. This arranges the detection electrode 11 provided inside the convex wall portion 26 of the housing 23 so as to be opposed to the detection target 21 via the convex wall portion 26 of the housing 23. As the detection target 21, not only a bare wire such as an overhead line but also an insulated and coated wire such as a power line can be applied. It is not necessary to bring the detection electrode 11 into direct contact with the bare wire or a core of a wire after an insulating and coating portion is removed therefrom.

In this state of use, in the AC generation unit 12 illustrated in FIG. 1, the piezoelectric element 14 is driven at an oscillation frequency that is output from the oscillation circuit 15, and, through giving oscillations at a resonance frequency of the piezoelectric element 14 (for example, 4 kHz) to the variable capacitor 13, the capacitance of the variable capacitor 13 is changed. Specifically, as illustrated in FIG. 4 and FIG. 5, through energizing the electrodes 32 and 33 of the piezoelectric element 14, the movable electrode portion 39 of the variable capacitor 13 fixed to the piezoelectric element 14 is oscillated with respect to the fixed electrode portion 36, thereby changing a distance between the fixed electrode portion 36 and the movable electrode portion 39 to change the capacitance of the variable capacitor 13. Through changing the capacitance of the variable capacitor 13, the AC current is generated.

The AC current generated in the AC generation unit 12 flows through a closed loop circuit of the AC generation unit 12—the current-to-voltage conversion circuit 16—the power supply circuit 19—the ground stray capacitance C₂—the ground—the detection target 21—the inter-electrode stray capacitance C₁—the AC generation unit 12. In this way, the AC current that is output from the variable capacitor 13 of the AC generation unit 12 is converted to the AC voltage by the current-to-voltage conversion circuit 16. The AC voltage that is output from the current-to-voltage conversion circuit 16 is synchronized at an oscillation frequency that is output from the oscillation circuit 15 by the synchronous detection circuit 17, and detection is performed.

At this time, the voltage that is input to the synchronous detection circuit 17 has, when the detection target 21 is in the charged state at the DC voltage of +400 V, the waveform as shown in FIG. 6A. When the detection target 21 is in the charged state at the DC voltage of −400 V, the waveform is as shown in FIG. 7A. Further, when the detection target 21 is in the power shut down state at the DC voltage of 0 V, the waveform is as shown in FIG. 8A. With regard to the waveforms in FIG. 6A, FIG. 7A, and FIG. 8A, only half waves are inverted through synchronous detection by the synchronous detection circuit 17. In other words, the voltage that is output from the synchronous detection circuit 17 has, when the detection target 21 is in the charged state at the DC voltage of +400 V, the waveform shown in FIG. 6B. When the detection target 21 is in the charged state at the DC voltage of −400 V, the waveform is as shown in FIG. 7B. Further, when the detection target 21 is in the power shut down state at the DC voltage of 0 V, the waveform is as shown in FIG. 8B.

Through smoothing (conversion to direct current), by the smoothing circuit 18, the voltage that is output from the synchronous detection circuit 17 obtained in this way, DC voltages of the detection target 21 at output levels shown in FIG. 6B, FIG. 7B, and FIG. 8B are output. Based on the voltage that is output from the smoothing circuit 18, a light or a beeper (not shown) connected to the smoothing circuit 18 and provided in the housing 23 is operated. For example, when the detection target 21 is in the charged state at the DC voltage of +400 V or −400 V, a worker is informed of the state through lighting of the light or sound of the beeper. Further, when the detection target 21 is in the power shut down state at the DC voltage of 0 V, a worker is informed of the state through turning off of the light or preventing the beeper from producing sound.

In this way, the presence or absence of the DC voltage in the detection target 21 can be detected based on the AC current that is output from the AC generation unit 12. In this way, the AC current flows through the inter-electrode stray capacitance C₁ formed between the detection target 21 and the detection electrode 11 and the ground stray capacitance C₂ formed between the internal shield 30 and the ground, and thus, not only a bare wire such as an overhead line but also an insulated and coated wire such as a power line can be the detection target 21, and versatility of the DC voltage detector is increased. Further, the necessity of a grounding line of the DC voltage detector is eliminated, and thus, workability in electrical work using the DC voltage detector can be improved and the DC voltage detector can be smaller and lighter.

Further, the internal shield 30 is formed on portions excluding the detection electrode 11, that is, excluding the convex wall portion 26 of the lower housing 25 to which the detection electrode 11 is adhered and the concave wall portion 27 of the upper housing 24, and thus, not only the structural components mounted on the wiring board 22 are protected against external noise but also the ground stray capacitance C₂ formed between the internal shield 30 and the ground can be enlarged to the maximum of a capacity of the housing. Thus, the AC current can be generated with ease in the AC generation unit 12.

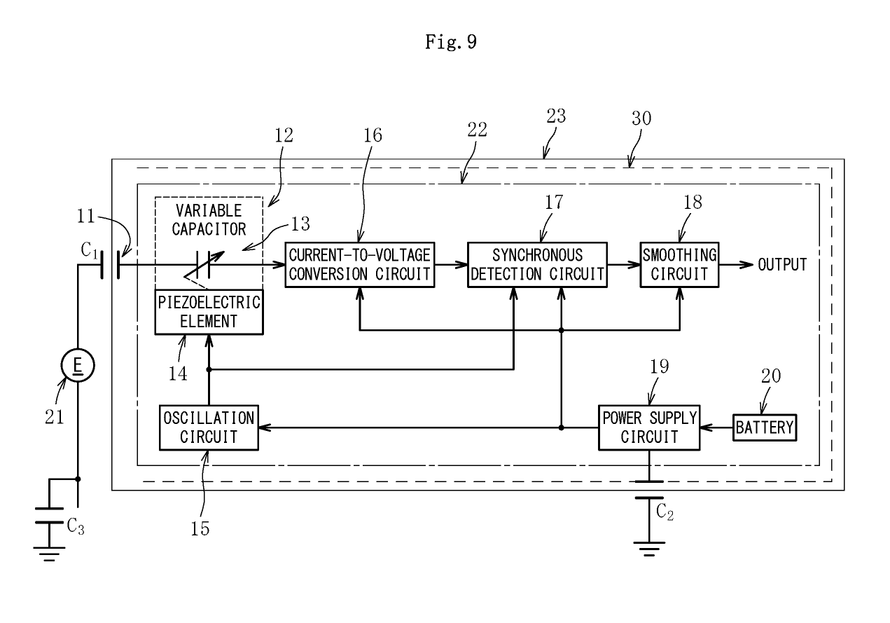

In the embodiment illustrated in FIG. 1, a case in which the detection target 21 comprises a grounding circuit is described, but the present invention can be applied not only to the case in which the detection target 21 comprises a grounding circuit but also to a case in which the detection target 21 comprises a neutral point grounding circuit or a non-grounding circuit. FIG. 9 is an illustration of an embodiment in which the DC voltage detector according to the present invention is applied to the detection target 21 comprising a non-grounding circuit. A configuration and operation of the DC voltage detector illustrated in FIG. 9 are similar to those of the embodiment illustrated in FIG. 1, and thus, redundant description thereof is omitted.

When the detection target 21 includes a grounding circuit, the presence or absence of the DC voltage can be detected through related-art ground connection of the grounding line. When the detection target 21 includes a non-grounding circuit, the presence or absence of the DC voltage cannot be hitherto detected. Through using the DC voltage detector according to the present invention comprising the AC generation unit 12 according to the present invention, even when the detection target 21 includes anon-grounding circuit, a ground stray capacitance C₃ of the detection target 21 is far larger than the inter-electrode stray capacitance C₁ as illustrated in FIG. 9, thereby enabling the presence or absence of the DC voltage to be detected.

The present invention is not limited to the above-mentioned embodiment. As a matter of course, the present invention may be carried out in various modes without departing from the spirit of the present invention. The scope of the present invention is defined in claims, and encompasses equivalents described in claims and all changes within the scope of claims.

1. A DC voltage detector, which is configured to detect the presence or absence of a DC voltage in a detection target through bringing a detection electrode provided inside a housing to a vicinity of the detection target,
the DC voltage detector comprising an AC generation unit configured to generate an AC current corresponding to the DC voltage through changing a capacitance, the AC generation unit being arranged between an inter-electrode stray capacitance formed between the detection target and the detection electrode and a ground stray capacitance formed between an internal shield of the housing and a ground.

2. The DC voltage detector according to claim 1, wherein the AC generation unit comprises:
a variable capacitor connected to an output side of the detection electrode; and
a piezoelectric element configured to change a capacitance of the variable capacitor.

3. The DC voltage detector according to claim 1, wherein the internal shield is formed on a portion inside the housing excluding the detection electrode.

4. The DC voltage detector according to claim 1, wherein the detection target comprises a grounding circuit.

5. The DC voltage detector according to claim 1, wherein the detection target comprises a non-grounding circuit.
